(19) United States
(12) Patent Application Publication
(10) Pub. No.: US 2020/0274190 A1
(43) Pub. Date: Aug. 27, 2020

(54) PARALLEL INTEGRATED NANO COMPONENTS (PINC) & RELATED METHODS AND DEVICES

(71) Applicant: INNOVASION LABS PINC, INC., San Diego, CA (US)

(72) Inventor: Inanc ORTAC, San Diego, CA (US)

(21) Appl. No.: 16/753,737

(22) PCT Filed: May 21, 2019
(86) PCT No.: PCT/US2019/033417

§ 371 Date: Apr. 3, 2020

Related U.S. Application Data
(60) Provisional application No. 62/674,471, filed on May 21, 2018.

(51) Int. Cl. H01M 10/058; H01L 31/075; H01L 33/06; H01G 4/008; H01G 4/12; H01G 4/38; H01L 33/24; H01L 31/0352; H01M 10/46

(52) U.S. Cl. CPC H01M 10/058; H01L 31/075; H01L 33/06; H01G 4/008; H01G 4/1209; H01M 2010/0495; H01G 4/1218; H01L 33/24; H01L 31/035218; H01L 31/035281; H01M 10/465; H01G 4/38

(57) ABSTRACT

Provided herein in accordance with the present invention, are nano-devices (or nano-components), composite-nano-devices, and methods of manufacturing and using the nano-devices and composite-nano-devices.

### TECHNICAL FIELD

The invention relates to nano-component energy devices and related methods.

### INTRODUCTION

The overall approach to building electronics components such as batteries and capacitors has not changed since their first invention around 18^{th} and 19^{th} century. In particular, for the case of capacitors and batteries, the improvements have mostly focused on the use of different materials for the electrodes, or anodes and cathodes. In particular, the overall structure of capacitors involves two electrodes separated by a dielectric material. For batteries, a cathode and anode is separated by a gap filled with an electrolyte material. There is an additional salt bridge that allows controlled diffusion of ions and often a separator for prevention of short circuits. The improvement of batteries has typically involved improving the energy density of the anode and cathode. Other developments include improvement of electrolyte material, improvement of chemistry mainly focused on the type of charge carrying ions. For capacitors, charge capacity of electrodes has been improved and the distance between the electrodes has been reduced to improve the electric field produced in between electrodes. Super capacitors have been developed, which allows the generation of an electric field between the electrode and double layer in solution, which essentially reduces the effective distance dramatically.

However, these approaches are not sufficient to address the need for higher capacity. Lithium has the highest electrochemical potential of all metals and highest energy density of all potential battery materials. However, electrochemical plating of lithium is known to generate dendrites that: reduce the efficiency, can short the battery, prevents safe operation of the cell, and can even cause a violent explosion.

Current attempted solutions to this problem include slowing down the recharging rate, inclusion of additives to the electrolyte, and addition of mechanisms to turn off cells when they exceed certain temperatures. These all increase the size, weight, and complexity of the batteries and reduces their practicality.

In the case of batteries, current approaches use anodes and cathodes that have a very high surface area due to their porosity and thus, high energy content. However, the ions still need to pass through electrolyte medium with limited diffusion and have separators that aim to prevent potential shorts between the anode and cathode. If the ions accumulate too fast and if they don't have time to settle and find allocated spots on the counter electrode, certain unwanted effects are observed, such as, e.g., the formation of dendrites in the case of lithium being used. These dendrites are structures that stick out of the surface and can short the anode and cathode, causing hazards such as, for example, an exothermic chain reaction resulting in an explosion. Although the surface areas of anodes and cathodes have improved over time, the electrolyte has not been improved, thus limiting the overall performance of the battery.

In the case of capacitors, having a very porous electrode structure (which is typically the main area for improvement) does not help much because what matters most is the distance between the two electrodes. However, having an essentially thicker electrode would end up producing a longer distance between the two extremes of the electrodes, thereby reducing the electric field amplitude that reduces the amount of charge stored within the electric field.

In short, for energy storage very high surface areas of electrodes are important; charge and discharge rates must be fast; safety is a big concern (i.e. Samsung Galaxy Note 7 incident); current batteries have very high energy density but slow charge/discharge; Li-ion batteries pose fire hazards; lithium ion batteries have high surface area cathodes, however, they need to limit the electrolyte ionic fluid flow because of fire hazard; capacitors have much faster charge and discharge but have low energy density; ultracapacitors have much higher energy density compared to capacitors but low voltage is a limitation because of a double layer, therefore they cannot reach a battery's energy capacity; and both ultracapacitors and lithium ion batteries have voltage limits although high voltage is always desirable for storage applications.

Accordingly, new devices, as well as methods of using and methods of making energy devices are needed.

### SUMMARY

Provided herein in accordance with the present invention, are nano-devices (or nano-components), composite-nano-devices, and methods of manufacturing and using the nano-devices and composite-nano-devices. Also provided herein are methods of manufacturing composite nano-component devices, which instead of being made up of macro individual components, are made up of numerous connected nano/micro scale units (e.g., component), each unit essentially performing like a single device having all or some of the required components. As such, the cumulative effects of the numerous connected nano/micro scale units or components advantageously results in being comparable or much more effective than having a conventional macro device with individual macro units. In particular embodiments, each nano/micro scale unit (e.g., referred to herein as a nanocomponent) is either fully functional or nearly fully functional. Also provided herein are methods for making such devices. In particular embodiments, the nano-components can be parallel (PINC) or serially connected. In particular embodiments, the components can be self-assembled into such configuration. In certain embodiments, connections of each component can be made using an addressable polymer such as deoxyribonucleic acid (DNA), which in particular embodiments is metallized in order to improve conductivity (see FIG. 19 and Example 11).

In accordance with the present invention, provided herein is a nano-device, wherein the nano-device comprises: an inner spherical core forming a first pole; an optional separator layer positioned between the inner core and the outer layer; and an outer layer forming a second pole (see, e.g., FIG. 13). The nano-device can further comprise an external coating layer (see, e.g., FIG. 13).

In a particular embodiment, the nano-device is a nano-battery: wherein the first pole is a first electrode; wherein the separator layer comprises a material that is porous to allow ion diffusion; and wherein the second pole is a second electrode that is opposite from the first electrode (see, e.g., FIG. 13).

In one embodiment, the nano-device is a nano-capacitor: wherein the first pole is a first electrode; wherein the separator layer comprises a dielectric material; and wherein the second pole is a second electrode that is opposite from the first electrode (see, e.g., FIG. 13).

In another embodiment, the nano-device is a nano-solarcell: wherein the first pole is either a p-type or n-type semiconductor; wherein the separator layer comprises a light sensitive intrinsic semiconductor; and wherein the second pole is a second p-type or n-type semiconductor that is different than the first semiconductor (see, e.g., FIG. 13).

In another embodiment, the nano-device is a nano-LED: wherein the first pole is either a p-type or n-type semiconductor; and wherein the second pole is a second p-type or n-type semiconductor that is different than the first semiconductor (see, e.g., FIG. 13).

Also provided herein is a nano-battery comprising: an inner spherical core forming a first electrode; a separator layer positioned between the inner core and the outer layer; and an outer layer forming a second electrode (see, e.g., FIG. 13). In particular embodiments, the separator layer is porous to allow ion diffusion. In particular embodiments of the invention nano-battery, if the first electrode is an anode, the second electrode is a cathode; or if the first electrode is a cathode, the second electrode is an anode.

Also provided herein is a composite-nano-device, comprising a first set and a second set of nano-devices as described hereinabove, wherein each of the first and second set has 1 or more single stranded oligonucleotides attached to the core forming a first pole and 1 or more single stranded oligonucleotides attached to the outer layer forming the second pole (FIG. 17). In one embodiment, in the first set, the single stranded oligonucleotide(s) attached to the core has an oligonucleotide sequence A, and the oligonucleotide(s) attached to the outer layer of the first set has an oligonucleotide sequence B, which is different from sequence A (FIG. 17). In another embodiment, in the second set, the single stranded oligonucleotide(s) attached to the core has an oligonucleotide sequence A′, which is complementary to A, and the oligonucleotide(s) attached to the outer layer of the second set has an oligonucleotide sequence B′, which is complementary to B (FIG. 17). In other embodiments, the first set and a second set of nano-devices are disposed within a chamber, wherein electrodes on the sides of the chamber have single stranded oligonucleotides attached thereto, wherein one electrode has a mixture of oligonucleotides A and A′ attached, and the other electrode has a mixture of oligonucleotides B and B′ attached. In a particular embodiment of the composite-nano-device, the first set and second set of nano-devices have self-assembled to form a lattice-like structure where the cores of substantially all of the nano-devices are connected with each other through a network of double stranded DNA produced by the hybridization of A and A′; and the outer layers of substantially all of the nano-devices are connected with each other through a network of double stranded DNA produced by the hybridization of B and B′. In particular embodiments, the core network is also connected with the electrode having said mixture of A and A′ oligonucleotides attached, and the outer layer network is connected to the electrode having said mixture of B and B′ oligonucleotides attached.

Also provided herein is composite-battery-device comprising: a plurality of nano-batteries, wherein each nano-battery is attached to at least 2 nanowires (see, e.g., FIGS. 7-9); and a plurality of nanowires, wherein said plurality of nanobatteries are integrated in parallel by the nanowires connected to metal contacts (see, e.g., FIG. 13). In particular embodiments, each of the at least 2 nanowires are operably connected to metal plates of opposing polarity, thereby forming a closed energy circuit (e.g., FIGS. 9 and FIG. 22G). In particular embodiments of the composite-battery-device, if the first electrode is an anode, the second electrode is a cathode; or if the first electrode is a cathode, the second electrode is an anode. In certain embodiments of the composite- battery-device, each respective nano-battery can further comprise an external insulating layer.

Also provided herein is a nano-capacitor comprising: an inner spherical core forming a first electrode; a separator layer comprising a dielectric material, wherein said separator layer is positioned between the inner core and the outer layer; and an outer layer forming a second electrode that is opposite from the first electrode (see, e.g., FIG. 13).

Also provided herein is a composite-nano-capacitor-device comprising: a plurality of invention nano-capacitors, wherein each nano-capacitor is attached to at least 2 nanowires (see, e.g., FIGS. 7-9); and a plurality of nanowires, wherein said plurality of nano-capacitors are integrated in parallel by the nanowires connected to metal contacts (see, e.g., FIG. 13).

Also provided herein is a nano-solarcell comprising: an inner spherical core forming a first semiconductor that is either a p-type or n-type semiconductor; a separator layer comprising a light sensitive intrinsic semiconductor, wherein said separator layer positioned between the inner core and the outer layer; and an outer layer forming a second p-type or n-type semiconductor that is different than the first semiconductor (see, e.g., FIG. 13).

Also provided herein is a composite-nano-solarcell-device comprising: a plurality of invention nano-solarcells, wherein each nano-solarcell is attached to at least 2 nanowires; and a plurality of nanowires, wherein said plurality of nano-solarcells are integrated in parallel by the nanowires connected to metal contacts (see, e.g., FIG. 13).

For the invention composite nano-devices provided herein, each one of the plurality of nano-devices is operably attached to at least 2 nanowires (see, e.g. FIGS. 7-9), wherein each of the at least 2 nanowires are operably connected to metal plates of opposing polarity, thereby forming a closed energy circuit (see, e.g., FIG. 9, FIG. 22G and FIG. 13). In particular embodiments, the nanowire comprises a metallo-nucleic acid nanowire (e.g., a gold-DNA hybrid, silver-DNA hybrid, or the like). In one embodiment, the nanowire comprises a silver-DNA hybrid nanowire. In particular embodiments, the nanowire has an insulating layer or coating surrounding it (see, e.g., FIG. 13).

In accordance with the present invention, it has been found that parallel connection of numerous nano-scale nano-devices (such as, for example, the invention nano-batteries or nano-capacitors provided herein; see, e.g., FIG. 13) in composite form containing a plurality of the respective nano-devices, instead of using one big battery or capacitor, results in lower cost while achieving very high energy density. The invention nano-devices (nano-units) can be self-assembled into a larger composite form using polymers, such as, for example, DNA addressed to electrodes or metal plates as described in the Examples herein and set forth in, e.g., FIGS. 7-11 and 13. In particular embodiments, the electrodes or metal plates have opposing polarity. One advantage provided herein is that if one or several individual nano-devices (or nano-components) fail, it has minimal impact on the overall device function because there are billions and/or trillions of nano-devices that are collectively integrated in parallel to form the overall composite-nano-device, such as, e.g., the composite-nano-battery or composite-nano-capacitor provided herein. Energy density is increased as the entire volume is utilized in the most effective way.

Other advantages with the nanobattery embodiment include, among others: overcoming the Li ion battery is limitation based on the voltage it can handle, which is based on the current density; instead of one device with large components, connected nanoscale devices (Parallel Integrated Nanoscale Components—PINC) are employed; each application is highly scalable and low cost; each application can use a variety of materials; battery application with connected nanoscale components; parallel connection of numerous nano scale batteries; the invention PINC configuration increases the total interaction volume dramatically reducing the ion current density; close to theoretical maximum energy density; rapid charge/recharge rates, for example, charge and recharge rates >100× faster than a traditional battery is contemplated herein; extremely fast recharging rates measure in seconds; high voltage without serial connection; a steady current; and overall improved safety.

For example, or the invention “composite-nano-battery” and nano-battery devices provided herein, the recharge and charge rate times can range from minutes to femtoseconds. Thus, in one embodiment the nano-battery or composite-nano-battery recharge rate times are selected from the group consisting of less than: 60′ (i.e., 60 min), 50′, 40′, 30′, 20′, 10′, 9′, 8′, 7′, 6′, 5′, 4′, 3′, 2′, and 1′. In another embodiment, the recharge rate times are selected from the group consisting of less than: 55 sec, 50 sec, 45 sec, 40 sec, 35 sec, 30 sec, 25 sec, 20 sec, 19, 18, 17, 16, 15, 14, 13, 12, 11, 10, 9, 8, 7, 6, 5, 4, 3, 2, and 1 second. In still a further embodiment, the recharge rate times are selected from the group consisting of less than: 1 second; 1 decisecond, 1 centisecond, 1 millisecond, 1 microsecond, 1 nanosecond, 1 picosecond, and less than 1 femtosecond. Likewise, for the invention “composite-nano-battery” and nano-battery devices provided herein, the charge rate times are selected from the group consisting of less than: 60′ (i.e., 60 min), 50′, 40′, 30′, 20′, 10′, 9′, 8′, 7′, 6′, 5′, 4′, 3′, 2′, and 1′. In another embodiment, the recharge rate times are selected from the group consisting of less than: 55 sec, 50sec, 45 sec, 40 sec, 35 sec, 30 sec, 25 sec, 20 sec, 19, 18, 17, 16, 15, 14, 13, 12, 11, 10, 9, 8, 7, 6, 5, 4, 3, 2, and 1 second. In still a further embodiment, the recharge rate times are selected from the group consisting of less than: 1 second; 1 decisecond, 1 centisecond, 1 millisecond, 1 microsecond, 1 nanosecond, 1 picosecond, and less than 1 femtosecond.

Other advantages with the nanocapacitor embodiment include, among others: Parallel connection of numerous nano scale capacitors; High capacitance of ultracapacitors; overcoming the High voltage of conventional capacitors; Extreme charge/discharge speeds of ultracapacitors; Extreme life-time/reliability of ultracapacitors; and the Safety and extreme lifetime of ultracapacitors; Safe and low cost materials will store extreme energy density due to nano scale gap between electrodes and extreme surface area; Extreme recharge rates; High stability and safety; and Essentially “infinite” lifetime.

In the case of the invention PINC nanocapacitor configuration, the effective electrode surface area increases dramatically while maintaining a very short distance of electrodes, therefore, one can still benefit from short distance between the electrodes and having an extremely long electrode surface area increasing capacitance. As the simulation in Example 14 and FIGS. 20 and 21 shows, it is contemplated herein to charge a capacitor much faster up to do theoretical levels of femtoseconds. In other embodiments, when the nanocapacitors are connected in parallel, the composite device will still be charged extremely fast, such as several orders of magnitude faster than seconds.

For the invention “composite-nano-capacitor” and nano-capacitor devices provided herein, the recharge and charge rate times can range from minutes to femtoseconds. Thus, in one embodiment the composite-nano-capacitor and nano-capacitor recharge rate times are selected from the group consisting of less than: 60′ (i.e., 60 min), 50′, 40′, 30′, 20′, 10′, 9′, 8′, 7′, 6′, 5′, 4′, 3′, 2′, and 1′. In another embodiment, the recharge rate times are selected from the group consisting of less than: 55 sec, 50 sec, 45 sec, 40 sec, 35 sec, 30 sec, 25 sec, 20 sec, 19, 18, 17, 16, 15, 14, 13, 12, 11, 10, 9, 8, 7, 6, 5, 4, 3, 2, and 1 second. In still a further embodiment, the recharge rate times are selected from the group consisting of less than: 1 second; 1 decisecond, 1 centisecond, 1 millisecond, 1 microsecond, 1 nanosecond, 1 picosecond, and less than 1 femtosecond. Likewise, for the invention “composite-nano-capacitor” and nano-capacitor devices provided herein, the charge rate times are selected from the group consisting of less than: 60′ (i.e., 60 min), 50′, 40′, 30′, 20′, 10′, 9′, 8′, 7′, 6′, 5′, 4′, 3′, 2′, and 1′. In another embodiment, the recharge rate times are selected from the group consisting of less than: 55 sec, 50 sec, 45 sec, 40 sec, 35 sec, 30 sec, 25 sec, 20 sec, 19, 18, 17, 16, 15, 14, 13, 12, 11, 10, 9, 8, 7, 6, 5, 4, 3, 2, and 1 second. In still a further embodiment, the recharge rate times are selected from the group consisting of less than: 1 second; 1 decisecond, 1 centisecond, 1 millisecond, 1 microsecond, 1 nanosecond, 1 picosecond, and less than 1 femtosecond.

Other advantages with the nanosolarcell embodiment include, among others: Parallel connection of numerous nano scale solar cells; Inhibition of exciton recombination by nanostructures; and a wide adjustable spectral response.

Other advantages with the nanoLED embodiment include, among others: use of Nanoscale light emitting diodes; and Multicolored, narrow emission spectra.

Other advantages with the nanoTherm embodiment include, among others: Parallel connections of nanoscale thermoelectric devices; and a composite Nanostructure that allows high electrical conductivity while providing low to no thermal conductivity.

### INCORPORATION BY REFERENCE

Herein, all issued patents, published patent applications, and non-patent publications that are mentioned in this specification are herein incorporated by reference in their entirety for all purposes, to the same extent as if each individual issued patent, published patent application, or non-patent publication were specifically and individually indicated to be incorporated by reference.

### BRIEF DESCRIPTION OF THE DRAWINGS

FIG. 1A-1B shows a nanowire attachment to a core (e.g., Pole 1).

FIG. 2 shows core surface functionalization/activation.

FIG. 3 shows inner shell growth.

FIG. 4 shows inner shell surface functionalization/activation.

FIG. 5 shows outer shell growth.

FIG. 6 shows nanowire attachment to an outer shell (e.g., Pole 2).

FIG. 7 shows outer shell coating/insulation.

FIG. 8 and FIG. 9 show the self-assembly of Parallel Integrated Nano Components (PINC).

FIG. 10 shows a composite nano-device made up of Parallel Integrated Nano Components (PINC).

FIG. 11A-11I shows a generalized method of manufacturing an invention Composite Nano-Capacitor Device.

FIG. 12A-E shows representative examples of size ranges of the invention nano-devices.

FIG. 13 shows a general model of an invention nano-device, including a nano-battery, nano-capacitor, nano-LED/Solar cell and an invention nano-thermoelectric.

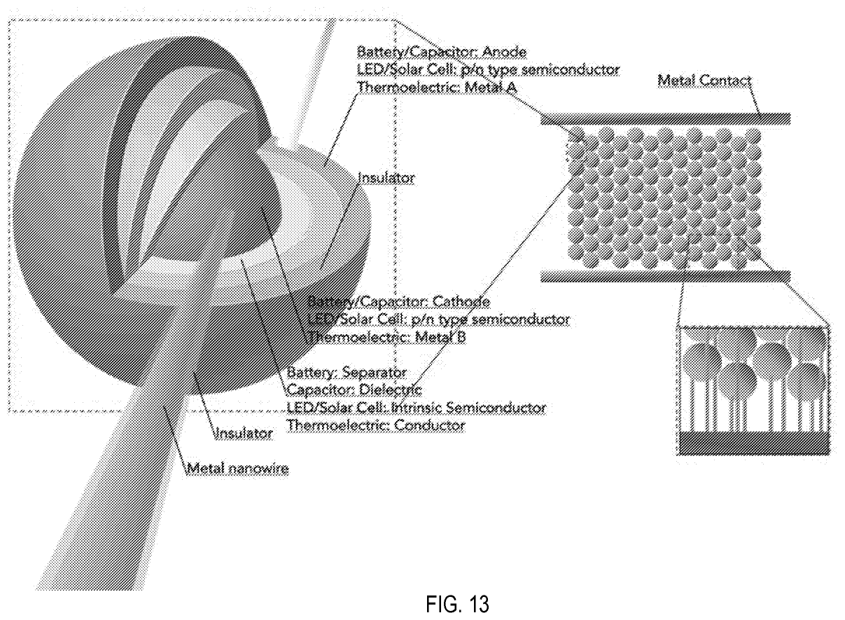

FIG. 14 shows generation of a cylinder-like gap by the DNA attached to a core.

FIG. 15 shows options for insulating the DNA nanowires or the outer shell.

FIG. 16 shows the connection of respective DNA nanowires to the both the core and opposite electrodes in a nano-device.

FIG. 17 shows the embodiment where 2 sets of nanocomponents are used in preparation of forming a lattice-like parallel integrated nanocomponent structure.

FIG. 18 shows the formation of a lattice-like parallel integrated nanocomponent structure by 2 sets of nanocomponents.

FIG. 19A-19C show exemplary embodiments of conductive nanowires.

FIG. 20 shows performance metrics for Capacitor geometries 1-3.

FIG. 21 shows time response performance metrics for Capacitor geometries 1-3.

FIG. 22A-22H show the Composite Nano-Capacitor Device Chemistry set forth in Example 9.

### DETAILED DESCRIPTION

Provided herein is a nano-device, wherein the nano-device comprises: an inner spherical core forming a first pole; an optional separator layer positioned between the inner core and the outer layer; and an outer layer forming a second pole. The nano-device can further comprise an external coating layer.

In a particular embodiment, the nano-device is a nano-battery: wherein the first pole is a first electrode; wherein the separator layer comprises a material that is porous to allow ion diffusion; and wherein the second pole is a second electrode that is opposite from the first electrode.

In one embodiment, the nano-device is a nano-capacitor: wherein the first pole is a first electrode; wherein the separator layer comprises a dielectric material; and wherein the second pole is a second electrode that is opposite from the first electrode.

In another embodiment, the nano-device is a nano-solarcell: wherein the first pole is either a p-type or n-type semiconductor; wherein the separator layer comprises a light sensitive intrinsic semiconductor; and wherein the second pole is a second p-type or n-type semiconductor that is different than the first semiconductor.

In another embodiment, the nano-device is a nano-LED: wherein the first pole is either a p-type or n-type semiconductor; and wherein the second pole is a second p-type or n-type semiconductor that is different than the first semiconductor.

### Batteries

Also provided herein is a nano-battery comprising: an inner spherical core forming a first electrode; a separator layer positioned between the inner core and the outer layer; and an outer layer forming a second electrode. In particular embodiments, the separator layer is porous to allow ion diffusion. In particular embodiments of the invention nano-battery, if the first electrode is an anode, the second electrode is a cathode; or if the first electrode is a cathode, the second electrode is an anode.

Instead of having one anode and one cathode, the invention composite nano-batteries utilize low capacity nano-scale batteries that are connected, preferably in parallel. Each anode and cathode is structured in a way that their thickness is minimal, preventing the formation of dendrites; and they are separated by a porous material that allows ions to flow.

Since the electrolyte passes through a very thin section, it is really fast moving. The likelihood of dendrite formation is very low as the current density is very low. In a particular embodiments, the nano-batteries and other nano-devices disclose herein are connected in parallel using nanowires, which permit high capacity.

As used herein, the term “nanowire” or “nanowires” refers to any material on a nano-scale level that is able to conduct an electric current, such as a metallo-nucleic acid, and the like. As used herein, the phrase “metallo-nucleic acid” refers to any hybrid of a conducting metal such as silver, gold, and the like; and any nucleic acid such as DNA, RNA, and the like. An exemplary nanowire for use herein is the silver-DNA hybrid nanowire and can be made as set forth in Kondo et al. (2017), Nature Chemistry, Vol. 9, Oct/2017: pages 956-960; Published Online: Jul. 3, 2017; DOI: 10.1038/NCHM.2808; which is incorporated herein by reference in its entirety for all purposes. Another silver-DNA hybrid nanowire contemplated for use herein is described and can be made as set forth in Braun et al., (Feb/1998) Nature, Vol 391, pgs. 775-778; which is incorporated herein by reference in its entirety for all purposes.

Heat dissipation is very efficient because, in this particular embodiment, each nano-unit battery is spherical resulting in the best surface area/volume ratio. Another advantage is that if one nano-battery fails, the rest of the nano-batteries connected in parallel (e.g., via the nanowires) still operate, such that the invention composite-battery remains operational/functional. Another advantage is that instead of requiring numerous manufacturing processes, once the nano-battery units are fabricated in bulk, the composite battery units are self-assembled, reducing the cost significantly.

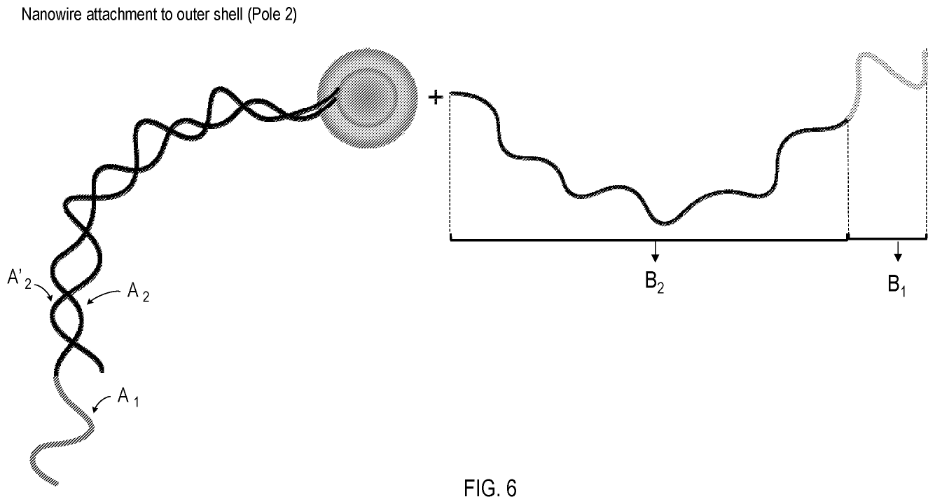

As used herein, the phrase “self-assembly” or “self-assembled” in the context of composite nano-device assembly, such as for nano-batteries, nano-capacitors, and the like described herein, refers to connecting nanowires (e.g., DNA nanowires) and their respective capture reagents (e.g., complementary oligonucleotides) to the invention nano-components and the respective metal contacts (e.g., opposite electrodes) such that, under suitable hybridization conditions, the nano-components self-assemble within the composite-nano-device or within the respective metal contacts (see FIGS. 6-9 and FIG. 11H-J, and the like).

In some embodiments, the nano-battery further comprises an external insulating layer. In particular embodiments, the insulating layer can cover the outer shell layer. In one embodiment of the nano-battery, the first electrode is a cathode-core comprising a material selected from the group consisting of: Bismuth Trioxide, Cobalt Oxide Particles, Iron Disulfide, Lithium Aluminum Alloy, Lithium Carbonate, Lithium Cobalt Oxide, Lithium Cobalt Phosphate, Lithium Hydroxide, Lithium Hydroxide, Lithium Iron Phosphate (LFP), Lithium Iron(III) Oxide, Lithium Manganese Dioxide, Lithium Manganese Nickel Oxide (LMNO), Lithium Manganese Oxide (LMO), Lithium Molybdate, Lithium Nickel Cobalt Aluminum Oxide, Lithium Nickel Cobalt Oxide, Lithium Nickel Dioxide, Lithium Nickel Manganese Cobalt Oxide (NMC), Lithium Silicon Alloy, Lithium Tin Alloy, Lithium Titanate, Lithium Titanate Spinel, Manganese(IV) Oxide, Nickel Hydroxide, Silver Chromate, Silver Oxide, and Vanadium Pentoxide

In certain embodiments of the nanobattery, the separator-layer comprises a material that is porous to allow ion diffusion. In particular embodiments of the nano-battery, the outer layer is an anode comprising a material selected from the group consisting of: Carbon, Copper Carbon, Copper Chloride, Copper Sulfide, Copper(II) Oxide, Graphene, Graphene Oxide Monolayer, Graphite, Manganese Selenide, Potassium Graphite, Pyrolytic Graphite, Silicon, Tin Oxide, lithium metal and Zinc.

In particular embodiments of the invention nanobattery, the diameter of the nanobattery is selected from the group consisting of: from about 1 nm to about 900 nanometers; from about 2 nm to about 500 nm; from about 3 nm to about 300 nm; from about 4 nm to about 200 nm; from about 5 to about 150 nm; from about 10 to about 150; from about 15 nm to about 150 nm; from about 15 nm to about 100 nm; 20 nm to about 75 nm; from about 25 nm to about 50 nm. In other embodiments of the nano-battery, the diameter of the core, or thickness for each of the separator layer and outer layer, are each selected from the group consisting of: 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, and 50 nm.

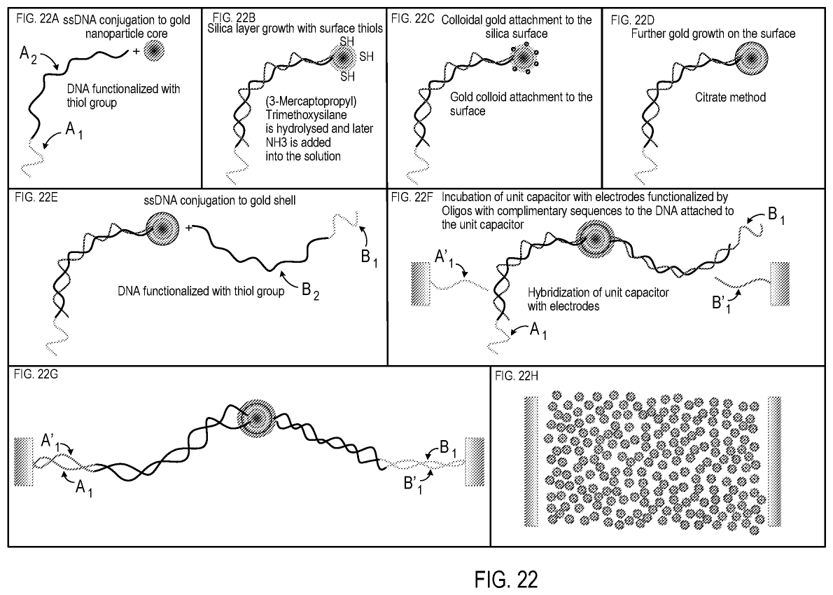

Also provided herein is composite-battery-device comprising: a plurality of nano-batteries, wherein each nano-battery is attached to at least 2 nanowires; and a plurality of nanowires, wherein said plurality of nanobatteries are integrated in parallel by the nanowires connected to metal contacts. In particular embodiments, each of the at least 2 nanowires are operably connected to metal plates of opposing polarity, thereby forming a closed energy circuit (e.g., FIG. 22G). In particular embodiments of the composite-battery-device, if the first electrode is an anode, the second electrode is a cathode; or if the first electrode is a cathode, the second electrode is an anode. In certain embodiments of the composite-battery-device, each respective nano-battery can further comprise an external insulating layer.

In accordance with the present invention, it has been found that parallel connection of numerous nano-scale nano-devices (such as, for example, the invention nano-batteries or nano-capacitors provided herein) in composite form (a “composite-nano-device”) comprising a plurality of the respective nano-devices, instead of using one big battery or capacitor, results in lower cost while achieving very high energy density, among other advantages. The invention nano-devices (nano-units) can be self-assembled into a larger composite form using polymers, such as, for example, DNA nanowires addressed to electrodes or metal plates as described in the Examples herein and set forth in the Figures. In particular embodiments, the electrodes or metal plates have opposing polarity. If one or several individual components fail, it has minimal impact on the device function. Energy density is increased as the entire volume is utilized in the most effective way.

As used herein, the phrase “composite-nano-device” as used in the context of a composite-nano-battery, composite-nano-capacitor, composite-nano-solarcell, composite-nano-LED, composite-thermoelectric-device, or the like, refers to a device that functions as a single electrical, conducting or energy unit by virtue of the integration, preferably in parallel, of a plurality of individual nano-devices, such that their individual energies or electrical or power or conductivity values are cumulative or added together and delivered from the overall composite-single-unit (e.g. a composite battery unit, a composite capacitor unit, a composite solarcell unit, a composite LED unit, and a composite thermoelectric unit). The number or volume of nano-devices (or nanocomponents) that can be combined in parallel to form an invention composite nano-device (e.g., a composite nano-battery, and the like) can be selected from the group consisting of at least: 10⁶, 10⁷, 10⁸, 10⁹, 10¹⁰, 10¹¹, 10¹², 10¹³, 10¹⁴, 10¹⁵, 10¹⁶, 10¹⁷, 10¹⁸, 10¹⁹, 1020 and at least 10²¹. ,

Thus, an invention composite-nano-battery refers to a plurality of invention nano-batteries integrated together in parallel to form one larger battery unit. Likewise, an invention composite-nano-capacitor refers to a plurality of invention nano-capacitors integrated together in parallel to form one larger capacitor unit. Likewise, an invention composite-nano-solarcell refers to a plurality of invention nano-solarcells integrated together in parallel to form one larger solarcell unit. Likewise, an invention composite-nano-LED refers to a plurality of invention nano-LEDs integrated together in parallel to form one larger LED unit. Likewise, an invention composite-nano-thermoelectric refers to a plurality of invention nano-thermoelectrics integrated together in parallel to form one larger thermoelectric unit.

In certain embodiments of the invention composite-battery-device, for each nano-battery therein, the first electrode is a cathode-core comprising a material selected from the group consisting of: Bismuth Trioxide, Cobalt Oxide Particles, Iron Disulfide, Lithium Aluminum Alloy, Lithium Carbonate, Lithium Cobalt Oxide, Lithium Cobalt Phosphate, Lithium Hydroxide, Lithium Hydroxide, Lithium Iron Phosphate (LFP), Lithium Iron(III) Oxide, Lithium Manganese Dioxide, Lithium Manganese Nickel Oxide (LMNO), Lithium Manganese Oxide (LMO), Lithium Molybdate, Lithium Nickel Cobalt Aluminum Oxide, Lithium Nickel Cobalt Oxide, Lithium Nickel Dioxide, Lithium Nickel Manganese Cobalt Oxide (NMC), Lithium Silicon Alloy, Lithium Tin Alloy, Lithium Titanate, Lithium Titanate Spinel, Manganese(IV) Oxide, Nickel Hydroxide, Silver Chromate, Silver Oxide, Vanadium Pentoxide

In particular embodiments, for each nano-battery within the composite-battery-device, the separator-layer comprises a material that is porous to allow ion diffusion. In certain embodiments of the invention composite-battery-device, for each nano-battery therein, the outer layer is an anode comprising a material selected from the group consisting of: Carbon, Copper Carbon, Copper Chloride, Copper Sulfide, Copper(II) Oxide, Graphene, Graphene Oxide Monolayer, Graphite, Manganese Selenide, Potassium Graphite, Pyrolytic Graphite, Silicon, Tin Oxide, lithium metal and Zinc.

In particular embodiments of the invention composite-nano-devices, such as the composite-battery-device, the diameter of each nano-device, such as, e.g., the invention nanobattery, is selected from the group consisting of: from about 1 nm to about 900 nanometers; from about 2 nm to about 500 nm; from about 3 nm to about 300 nm; from about 4 nm to about 200 nm; from about 5 to about 150 nm; from about 10 to about 150; from about 15 nm to about 150 nm; from about 15 nm to about 100 nm; 20 nm to about 75 nm; from about 25 nm to about 50 nm. In other embodiments of the invention composite-nano-device, such as for example, the composite-battery-device, for each nano-device therein, such as, for example, a nano-battery, the diameter of the core, or thickness for each of the separator layer and outer layer, are each selected from the group consisting of: 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, and 50 nm.

For the invention composite nano-battery-device provided herein, each one of the plurality of nano-batteries is operably attached to at least 2 nanowires, wherein each of the at least 2 nanowires are operably connected to metal plates of opposing polarity, thereby forming a closed energy circuit (e.g., FIG. 22G). In particular embodiments of the invention nano-battery device, the nanowire comprises a metallo-nucleic acid nanowire (e.g., a gold-DNA hybrid, silver-DNA hybrid, or the like). In one embodiment, the nanowire comprises a silver-DNA hybrid nanowire.

### Capacitors

In the case of capacitors, the previous improvements have focused on reducing the distance between the two electrodes and again increasing the charge capacity. However, increasing energy density by improving the porosity, thus effective thickness of the electrode does not always directly translate to energy capacity. In traditional capacitors, the electrodes can hold a great deal of charge, however the distance cannot be reduced much by existing materials. New generation capacitors try to increase the charge density of electrodes. Then, to reduce the distance they use a double layer. Use of double layers causes a very thin voltage barrier that generates an electric field. Since the electric field is inversely proportional with the distance, that very little layer helps to improve capacitance. However, the problem is that you cannot increase the total voltage, and thus the charge it carries because the double layer breaks when using high voltages.

In accordance with the present invention, provided is composite-capacitor that utilizes nano-unit (regular) capacitors, preferably connected in parallel, instead of a large super capacitor. In particular embodiments, the nano-capacitors are connected in parallel using nanowires as described herein. An advantage contemplated herein is the potential to reach high voltage capacity and high energy density. It has been found that it does not help to separately increase the energy density of two separate electrodes because they become three dimensional and the distance between two electrodes starts to become significant for the farther sides of the electrodes. Trying to solve that problem by using a double layer, which is limited by the total voltage still cannot address the high capacity need of the capacitors, as they become much lower energy density than batteries.

Accordingly, provided herein is a nano-capacitor comprising: an inner spherical core forming a first electrode; a separator layer comprising a dielectric material, wherein said separator layer is positioned between the inner core and the outer layer; and an outer layer forming a second electrode that is opposite from the first electrode. In particular embodiments of the nano-capacitor, the first and/or second electrode is a metal selected from the group consisting of gold, silver, iron and platinum., and the like, such that the first and second electrodes can comprise the same or different metals. Thus, those of skill in the art will understand that the first electrode “and” second electrode; as well as the first electrode “or” the second electrode is a metal selected from the group consisting of gold, silver, iron and platinum., and the like. In particular embodiments of the nano-capacitor, the dielectric material forming the separator layer is an oxide selected from the group consisting of MgO, TiO₂, SiO₂, or any mixture thereof, and the like.

Also provided herein is a composite-nano-capacitor-device comprising: a plurality of invention nano-capacitors, wherein each nano-capacitor is attached to at least 2 nanowires; and a plurality of nanowires, wherein said plurality of nano-capacitors are integrated in parallel by the nanowires connected to metal contacts.

### Solar Cells

Solar cells are usually a p-i-n junction, where there is a stationary electric field because of the charge imbalance between the p and n junctions. There is also an optically sensitive intrinsic region, and when the photons hit the intrinsic region, an electron is kicked off a nucleus forming. With the electric field it is separated and flows with respect to the direction of the electric field. The problem is that if the distance for the electron to go through is long, then there is a very high likelihood that recombination will affect the overall efficiency. If the electric field separation is long, although there are more active regions for photon interaction, as the photon travels there is a higher likelihood of recombination. Narrowing the gap in the electric field separation reduces the chance of recombination, however, it also reduces the active area.

The invention nano-solar cell and composite-solar cell utilize a sweet spot. For example, having invention nano-solar cells in parallel connection with each other (e.g., to form an invention composite-solar cell), provides a composite-solar cell (also referred to herein as a unit solar cell), with a very thin active area that is transparent, however at the same time, their electrodes are very thin and transparent letting the light through. Therefore all the active area advantageously has access to the sunlight.

Accordingly, provided herein is a nano-solarcell comprising: an inner spherical core forming a first semiconductor that is either a p-type or n-type semiconductor; a separator layer comprising a light sensitive intrinsic semiconductor, wherein said separator layer positioned between the inner core and the outer layer; and an outer layer forming a second p-type or n-type semiconductor that is different than the first semiconductor.

Also provided herein is a composite-nano-solarcell-device comprising: a plurality of invention nano-solarcells, wherein each nano-solarcell is attached to at least 2 nanowires; and a plurality of nanowires, wherein said plurality of nano-solarcells are integrated in parallel by the nanowires connected to metal contacts.

For the invention composite nano-devices provided herein, each one of the plurality of nano-devices is operably attached to at least 2 nanowires, wherein each of the at least 2 nanowires are operably connected to metal plates of opposing polarity, thereby forming a closed energy circuit (e.g., FIG. 22G). In particular embodiments, the nanowire comprises a metallo-nucleic acid nanowire (e.g., a gold-DNA hybrid, silver-DNA hybrid, or the like). In one embodiment, the nanowire comprises a silver-DNA hybrid nanowire.

### Thermoelectric

Thermoelectric devices provided herein have low thermal conductivity while having high electrical conductivity, which allow them to become very efficient thermoelectric devices. In accordance with the present invention, it is contemplated that having nano components (e.g., thermoelectric deices) instead of having a device with macro components provides benefits that improves the device performance dramatically. When the size of a nanostructure is comparable with the mean free path (MFP) of a phonon, the collision of phonons with the boundary is much more frequent than in bulk materials. That way the resistance to heat flow increases and the effective thermal conductivity is decreased (Chen, G. Phonon heat conduction in nanostructures. Int. J. Therm. Sci. 4, 471-480 (2000); which is incorporated herein by reference in its entirety for all purposes). Moreover, again in the case of MFP of phonons being comparable with the dimensions of the device, phonons become rarefied increasing the thermal resistance. In addition, the phonon spectra can also be altered in a way that allows low thermal conductivity (Chen, G. Phonon heat conduction in nanostructures. Int. J. Therm. Sci. 4, 471-480 (2000)). Therefore, the invention methods (PINC) and nano-thermoelectric devices provided herein allows such structures where thermal conduction is very low while electrical conduction is still high, achieving dramatic increases in efficiency of thermoelectric devices.

### EXAMPLES

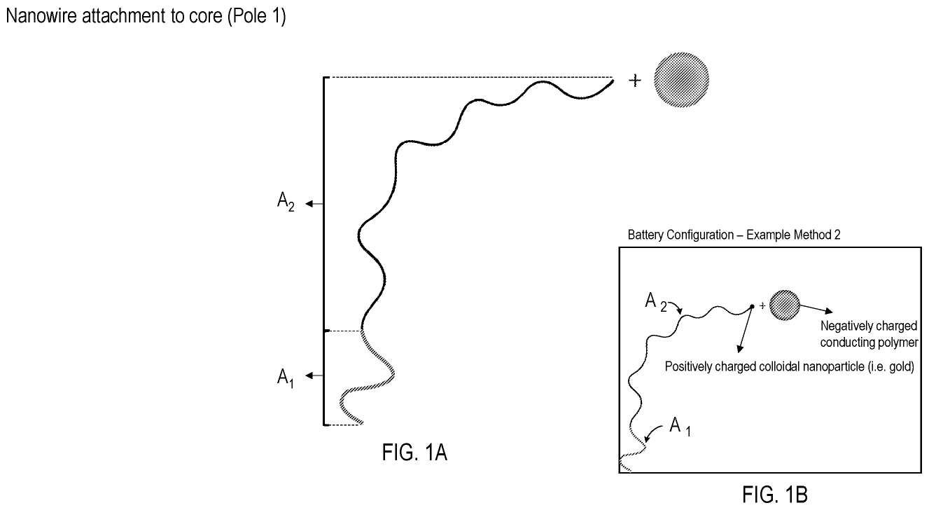

### Example 1—Nanowire Attachment to the Core (FIG. 1):

### Capacitor Configuration—Gold-Silica-Gold

Metal (i.e. gold, silver, iron and platinum) nanoparticles (e.g., invention nano-devices) are suspended in solution. Thiol modified single strand DNA (or in other embodiments, double-stranded DNA or RNA can be utilized) oligonucleotides (or other organic, inorganic polymers such as peptides, polyaminoacids, or the like) are incubated in solution with colloidal metal nanoparticles. One or more oligonucleotides are attached to the colloidal nanoparticles as depicted in FIG. 1B.

### Battery Configuration—LiCoO2-Silica-GrapheneOxide

Method 1: Oligonucleotide functionalized with negatively charged groups such as carboxyls (or hydroxyls, phosphates, and the like) are incubated with colloidal nanoparticle core materials. The other end of the oligonucleotide has a particular coding sequence (Sequence A) that is typically 5-20 base pairs long (FIG. 1A).

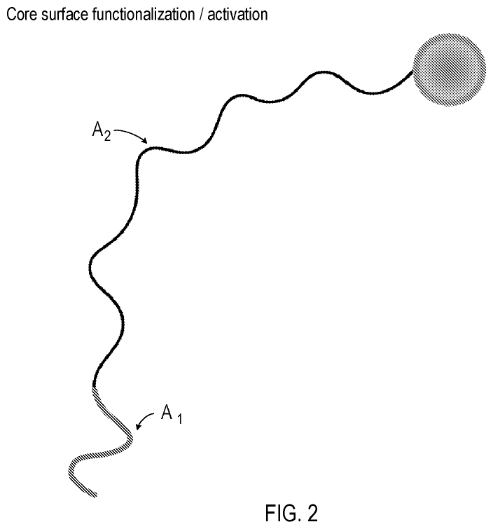

Method 2: A Cathode core (corresponding to the inner spherical core) is coated with a negatively charged conducting polymer such as PEDOT/PSS (poly(3,4-ethylene-dioxythiophene)/poly(4-stylenesulphonic acid)) or the like (FIG. 1B). Then, an oligonucleotide conjugated to a nanoparticle (such as gold) from one end is incubated with the coated core for the oligonucleotides to be adsorbed to the core surface (see FIG. 1B and FIG. 2). Suitable “cathode” material for use herein includes, but is not limited to, Bismuth Trioxide, Cobalt Oxide Particles, Iron Disulfide, Lithium Aluminum Alloy, Lithium Carbonate, Lithium Cobalt Oxide, Lithium Cobalt Phosphate, Lithium Hydroxide, Lithium Hydroxide, Lithium Iron Phosphate (LFP), Lithium Iron(III) Oxide, Lithium Manganese Dioxide, Lithium Manganese Nickel Oxide (LMNO), Lithium Manganese Oxide (LMO), Lithium Molybdate, Lithium Nickel Cobalt Aluminum Oxide, Lithium Nickel Cobalt Oxide, Lithium Nickel Dioxide, Lithium Nickel Manganese Cobalt Oxide (NMC), Lithium Silicon Alloy, Lithium Tin Alloy, Lithium Titanate, Lithium Titanate Spinel, Manganese(IV) Oxide, Nickel Hydroxide, Silver Chromate, Silver Oxide, Vanadium Pentoxide, and the like.

### Common to All Configurations

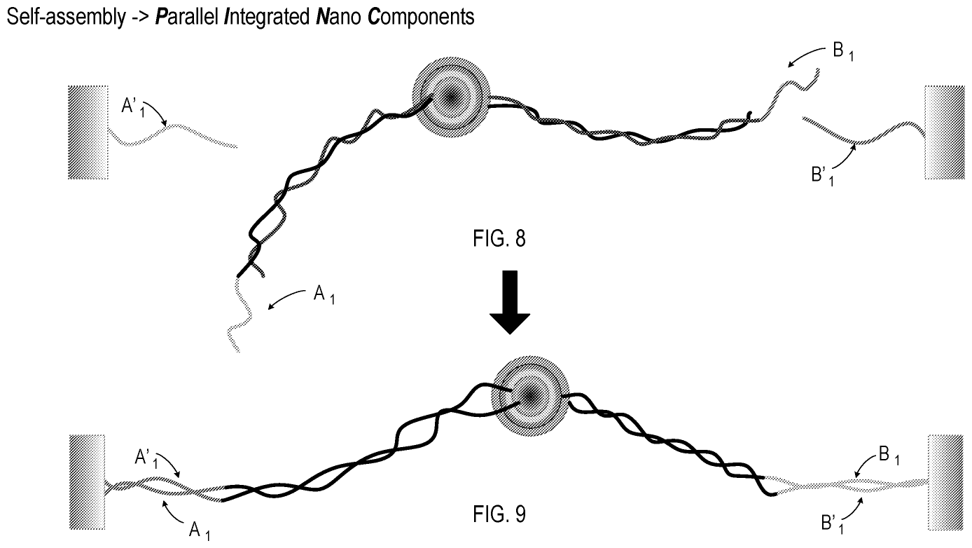

The oligonucleotide has a particular nucleotide sequence made up of two sub-sequences: A1 and A2 (FIG. 1A and FIG. 2). The sequence A1 is typically 5-20 base pairs long that will be the sequence used to address the core to one of the metal contacts (Pole 1) via a complementary oligonucleotide sequence attached to the respective metal contact. The other sequence is A2 can be hybridized with a complementary strand A2′, which in certain embodiments, is contemplated to add stability to the nanowire and/or enable electrical conductivity based on the method used to make it conductive. The length of A2 can be adjusted based on the desired separation of two metal contacts (Pole 1 and 2; see FIG. 1A, FIG. 8 and FIG. 9).

### Example 2—Core Surface Functionalization/Activation (FIG. 2):

Capacitor configuration—Gold-Silica-Gold: Gold nanoparticles surface are functionalized for stabilization and/or further growth by a silane (i.e. (3-mercaptopropyl) trimethoxy silane (MPTMS), where thiol groups attach to the surface expressing silanes on the surface; or by (3-aminopropyl) triethoxysilane (or methoxy silane) (APTES/APTMS), where silane groups are attracted to the surface, expression both silanes and amine groups on the surface; or by chloromethyl-silane (CTMS), and the like. If applicable, the oligonucleotide is hybridized with the A2′ complementary strand. In certain embodiments herein, the DNA is single stranded as there are various methods known in the art to make single stranded DNA conducting. However, in other embodiments, it is contemplated herein to use double stranded DNA for stability purposes. See, for example, the methods set forth in Kondo, J. et al. A metallo-DNA nanowire with uninterrupted one-dimensional silver array. Nat. Chem. 9, (2017); Rakitin, A. et al. Metallic conduction through engineered DNA: DNA nanoelectronic building blocks. Phys. Rev. Lett. 86, 3670-3673 (2001); and Xia et al.: Metal-organic frameworks and their derived nanostructures for electrochemical energy storage and conversion. Energy Environ. Sci. 8, 1837-1866 (2015); each of which is incorporated herein by reference in their entirety for all purposes).

### General Sol-Gel (i.e. Silica, Titania) Chemistry for All Configurations

Core surface, or coated core surface is further functionalized for stabilization and/or further growth by (3-mercaptopropyl) trimethoxy silane, where thiol groups attach to the surface expressing silanes on the surface, or (3-aminopropyl) trimethoxysilane (or metoxysilane) (APTES/APTMS), where silane groups are attracted to the surface, expression both silanes and amine groups on the surface. In particular embodiments, the surface is further coated with an oxide such as MgO, TiO2, SiO2 or their mixtures as set forth in Hong, W. & Ming-Cai, C. Modification of LiCoO2 by Surface Coating with MgO/TiO2/SiO2 for High-Performance Lithium-Ion Battery. Electrochem. Solid-State Lett. 9, A82-A85 (2006); which is incorporated herein by reference in its entirety for all purposes). If applicable, oligonucleotide is hybridized with the complementary strand. In certain embodiments herein, the DNA is single stranded as there are various methods known in the art to make single stranded DNA conducting. However, in other embodiments, it is contemplated herein to use double stranded DNA for stability purposes. (See Kondo et al. 2017; Rakitin et al. 2001; and Xia et al. 2015; which are incorporated herein by reference in their entirety for all purposes).

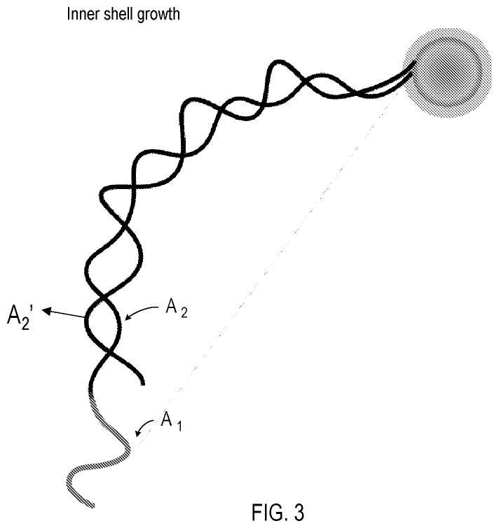

### Example 3—Inner Shell is Growth (FIG. 3):

The well-known Sol-gel process (e.g., the Stober process, or modified versions of it) is used to further grow silica as the inner shell on top of the core. The process involves using silanes on the surface as nucleation sites and silicic acid as precursor for silica polycondensation reaction. See, for example, the methods described in Ortac, I. et al. Dual-Porosity Hollow Nanoparticles for the Immunoprotection and Delivery of Nonhuman Enzymes. Nano Lett. 14, 3023-3032 (2014); and Yang, J., Lind, J. U. & Trogler, W. C. Synthesis of Hollow Silica and Titania Nanospheres. Chem. Mater. 20, 2875-2877 (2008); which are each incorporated herein by reference in their entirety for all purposes. Further dissolution or an eventual calcination allows formation of a nano/mesoporous solid (or solid like) inner shell allowing removal of hydroxyls and making the layer less conductive electrically. A separation layer formed by sol-gel (i.e. silica sol-gel) layer provides the porosity for ion conduction suitable for invention battery applications.

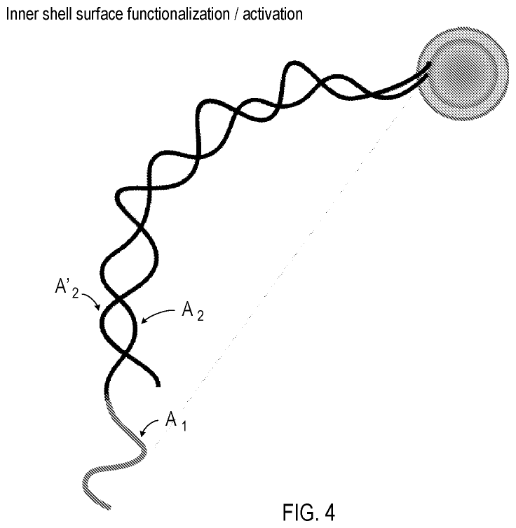

### Example 4—Inner Shell Surface Functionalization/Activation (FIG. 4):

In particular embodiments, the inner surface can be further functionalized by a silane (i.e. MPTMS, APTES, APTMS, and CMTS). For example, MPTMS can be used to add thiol groups expressed at the surface. This step is optional as a result of most oxide processes, which typically result in the surface charge carrying a negative charge.

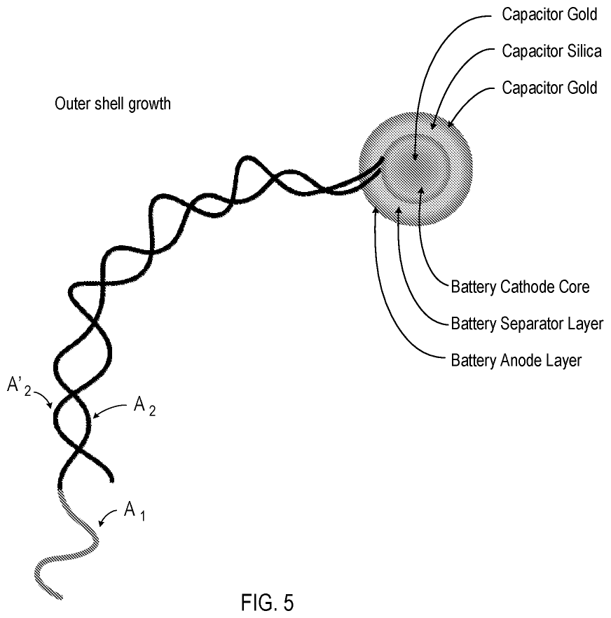

### Example 5—Outer Shell Growth (FIG. 5):

### Capacitor Configuration—Gold-Silica-Gold

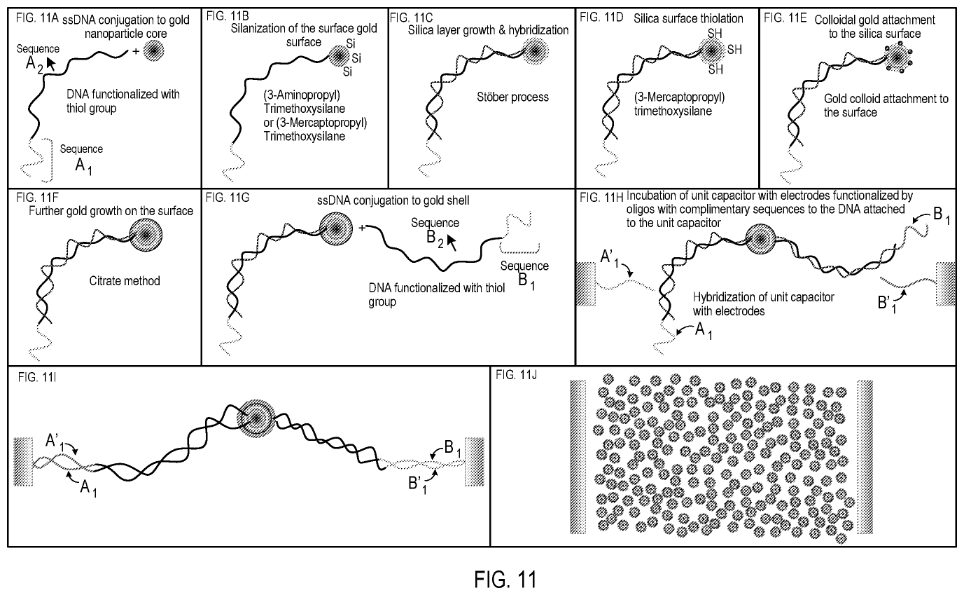

To facilitate the growth of the gold outer shell, colloidal gold nanoparticles ranging in size from about 1 to about 10 nm (in other embodiments, both smaller or larger nanoparticles are contemplated for use herein) are adsorbed onto the surface to be utilized as nucleation sites for outer shell growth gold (see FIG. 11E). Using the well-known citrate method, gold nanoparticles adsorbed to the surface are used as nucleation sites to reduce auric acid on the surface to grow gold nanoparticles and merge them eventually to have gold layer.

### Battery Configuration—LiCoO2-Silica-GrapheneOxide

As the inner shell corresponding to the inner spherical core (e.g., a cathode-core in this particular embodiment) expresses a negative charge, it can attract graphene/graphene oxide sheets to the surface, as those sheets wrap around the inner shell, they form an outer shell to act as an anode as set forth in Joo, J. et al. Porous silicon-graphene oxide core-shell nanoparticles for targeted delivery of siRNA to the injured brain. Nanoscale Horiz. 1, 407-414 (2016); which is incorporated herein by reference in its entirety for all purposes. Suitable Anode materials for use herein, include but are not limited to: Carbon, Copper Carbon, Copper Chloride, Copper Sulfide, Copper(II) Oxide, Graphene, Graphene Oxide Monolayer, Graphite, Manganese Selenide, Potassium Graphite, Pyrolytic Graphite, Silicon, Tin Oxide, lithium metal and Zinc.

### Example 6—Nanowire attachment to outer shell (Pole 2) (FIG. 6):

### Capacitor configuration—Gold-Silica-Gold

As set forth herein, using thiol terminated DNA, DNA is attached to the outer shell surface.

### Battery Configuration—LiCoO2-Silica-GrapheneOxide

In particular to Graphene Oxide, DNA is attached to the outer shell using an amide condensation reaction as Graphene Oxide has abundant oxygen-containing groups as set forth in Yuqi, et al.: Graphene based materials for biomedical applications. Mater. Today Vol. 16, 365-373 (2013); which is incorporated herein by reference in its entirety for all purposes.

### Common to All Configurations

As set forth in FIG. 6, the single stranded oligonucleotide has a particular sequence made up of two sequences: B1 and B2. The sequence A1 and B1 is typically 5-20 base pairs long and will be the nucleotide base sequence used to address the core to one of the metal contacts (Pole 2) via a complementary sequence attached to the metal contact (see, e.g., B1′ in FIG. 8). However in particular embodiments, the A1 and B1 sequence lengths can be much longer, such as for example 20 bp up to a few kilo base pairs. In other embodiments, A1 and B1 can range from 20 bp up to about 200 bp, with about 20 bp up to about 60 bp being most common. The other sequence is B2 and can be hybridized with a complementary strand B2′, which in certain embodiments, is contemplated to add stability to the nanowire and/or enable electrical conductivity based on the method used to make it conductive. The length of B2 can be adjusted based on the desired separation of two metal contacts (Pole 1 and 2; see FIG. 9).

Exemplary lengths contemplated herein for the lengths of both A2 and B2 in FIGS. 6-9 (and FIG. 11H-J), can be varied and staggered in order to facilitate the interior structure and spacing of the individual nanocomponents within an invention composite nano-device. For example, for each respective nanocomponent structure described herein (e.g., nano-battery, nano-capacitor, nano-nano-solar cell, and the like), the length of the DNA nanowire attached to the core (e.g., a battery cathode) can be staggered and selected to be either very short relative to the overall length of the device, or the overall length between the 2 metal contacts or electrodes; or it can be as long or longer than the overall length of the device or the distance between the 2 metal contacts or electrodes. Whereas for the same respective nanocomponent, the length of the length of the DNA nanowire attached to the outer shell (e.g., a battery anode) can be staggered and selected to be either very short relative to the overall length of the device, or the overall length between the 2 metal contacts or electrodes; or it can be as long or longer than the overall length of the device or the distance between the 2 metal contacts or electrodes. Where the lengths of A2 and B2 are equidistant and approximately half the distance of the device or half the distance between the metal contact or electrodes, that particular nanocomponent will be limited to position itself in the middle of the device or the metal contacts. By staggering the length of A2 to be at least between 1 nucleotide up to the length of an oligonucleotide that is half the distance of the device or the distance of the metal contacts or the electrodes; and also staggering the respective B2 oligonucleotide to be the inverse distance (e.g., when A2 is short, B2 is long; when A2 is 1 ntd, B2 is at least the length of the entire distance of the device or the entire distance between the metal contact or the electrodes), the relative location of the nanocomponents self-assemble within the device or within the metal contacts or electrodes is controlled to facilitate uniform distribution.

In another embodiment, the lengths of A2 and B2 in FIGS. 6-9 (and FIG. 11H-J), can both be at least the length of the entire composite-nano-device or the entire distance between the metal contacts or electrodes. In this embodiment, when the nano-components self-assemble within the device, each nano-component is free to randomly pack itself at any location within the composite nano-device.

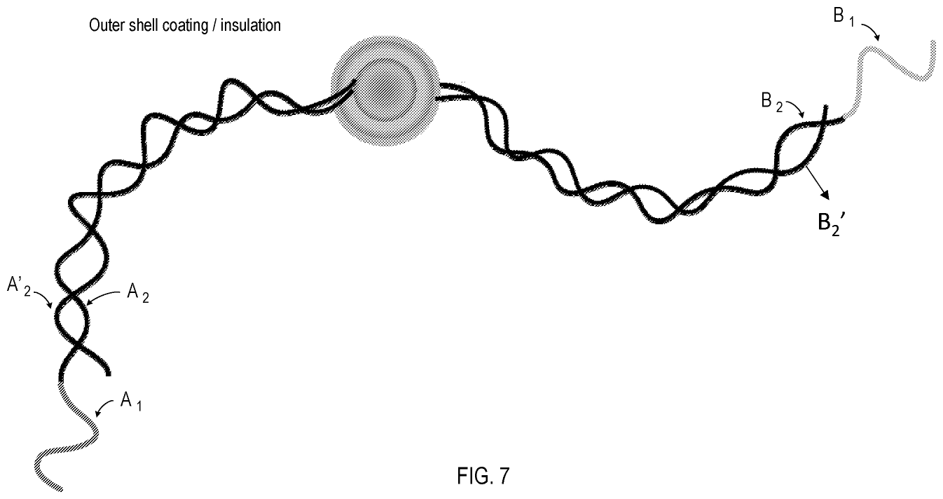

### Example 7—Outer Shell Coating/Insulation (FIG. 7):

The outer shell can be further coated using a polymer insulating layer, such as, e.g., using a polymer that could be of opposite charge, or using another layer of oxide, such as silica, or the like. This coating step can utilize an approach similar to the one used above for the inner shell.

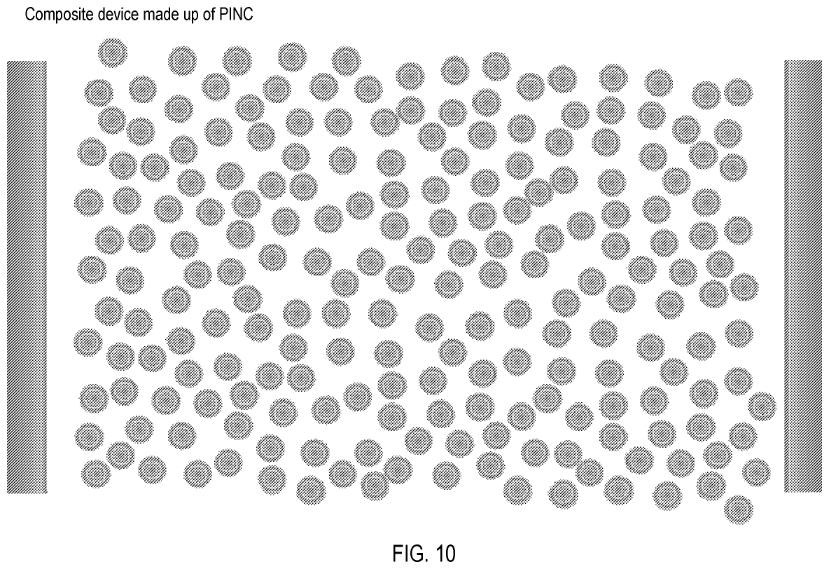

### Example 8—Self-Assembly Into Parallel Integrated Nano Components (FIGS. 8-10):

In this particular embodiment, there are two kinds of metal contacts that would link each particle to the outer circuit. A first metal contact with one polarity has a plurality of oligonucleotides attached to it with a particular sequence (Sequence A1′) complementary to Sequence A1 (FIG. 8 and FIG. 11H). While a second metal contact having the opposite polarity of the first metal contact has a plurality of oligonucleotides attached to it carrying a sequence different than A1′, corresponding to Sequence B1′ complementary to Sequence B1 (see FIG. 8 and FIG. 11H). This step ensures that the inner spherical core is connected to one contact (e.g., a first metal contact in this embodiment) while the outer shell is connected to the other contact (e.g., the second metal contact with opposing polarity in this embodiment). This prevents the two poles of the nano-component attaching to the same contact, thus generating a short.

In this step, the nanocomponents (e.g., invention nano-devices, such a nano-battery or nano-capacitor provided herein) with DNA tags (e.g., at the ends of either staggered A2 and B2 DNA nanowire lengths or full device length A2 and B2 nanowires) are incubated long enough using well-known hybridization conditions to allow hybridization of each nanocomponent tag with its complementary oligo (either A1′ or B1′) attached to the metal contact, resulting in the self-assembly of a composite nanocomponents or nano-devices (see FIGS. 8 & 9).

Finally, each nanocomponent is attached to the respective metal contacts with respect to the polarity of tags (FIG. 9) and each nanowire is metallized by this step. Then, in the embodiment of nano-capacitors, the solution can be changed to an electrically dielectric solution, gel, or polymer; and can be wet or dry based on the chemistry.

For the embodiment where composite nanobatteries are provided herein, an electrolyte solution is utilized.

In other embodiments contemplated herein, at various points during this procedure set forth as Examples 1-8 above (also set forth in detail with respect to a gold-silica-gold capacitor in FIG. 22, Panels A-G), DNA can be metallized to create conductive nanowires. So as not to interfere with the complementary hybridization steps, in certain embodiments, it is contemplated to be more advantageous to complete the metallization in a later step (such as, for example, panels FIG. 11H or FIG. 11I, and the like) to benefit from specific recognition of DNA strands. However, if any of the processes require dry or vacuum processing, DNA can be metallized first and solidified, which would make it resilient during such dry/vacuum process. Later, the solidified structure could be added into solution for further wet chemistry.

### Example 9—The Chemistry for a Composite Nano-Capacitor Device

As set forth in FIG. 22A, thiolated DNA is attached to the surface of gold nanoparticles.

As set forth in FIG. 22B, (3-Mercaptopropyl) Trimethoxysilane (MPTMS) is hydrolyzed initially and added to gold nanoparticles solution attached with DNA. NH3 is added to the solution resulting in growth of a silica layer.

As set forth in FIG. 22C, the silica surface presents thiol groups. Gold nanoparticles are added into the solution being attached to the surface silica surface through thiol-gold chemistry.

As set forth in FIG. 22D, using the well-known citrate method, gold nanoparticles attached to the surface template furthers the gold growth, merging gold nanoparticles to form a continuous gold layer.

As set forth in FIG. 22E, thiol functionalized DNA is attached to the outer shell.

As set forth in FIG. 22F, single stranded DNA is hybridized by its complementary strand.

As set forth in FIG. 22G, the sequence at the very end is used to address the DNA to each of the electrodes selectively hybridizing with the strands attached to the respective electrodes.

### Example 10—Exemplary Size Ranges

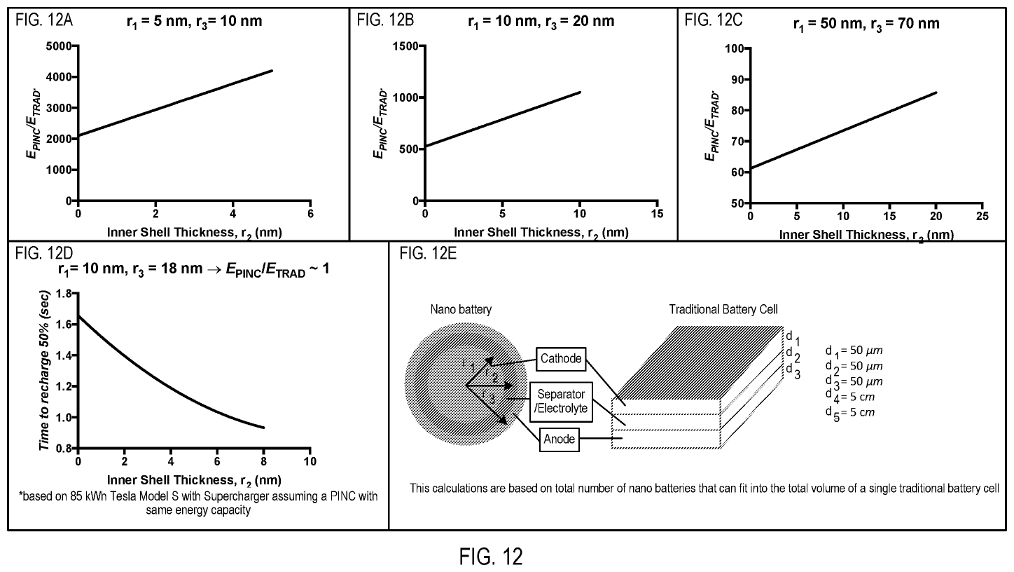

FIG. 12A-E provides some representative examples of exemplary size ranges of the invention nano-devices, including the invention nano-battery, and the like. The ratio of energy capacity of an invention composite nano-battery (Parallel Integrated Nano Component—PINC) to a traditional battery was plotted with respect to the inner shell diameter, corresponding to the separator layer of the invention nanobattery, at a few relevant points (top three plots corresponding to FIG. 12A-C). Also on the left, the energy ratio was kept at 1 and the recharging time was plotted.

As observed from FIG. 12, lithium, lithium-containing and lithium-based nanoparticles in the range of 10-50 nm are readily accessible. A silica layer can readily be grown in a range of 5 nm to 50 nm, and a graphene layer can readily be grown or deposited on top of the silica layer from 5-20 nm; which corresponds most closely to the top middle configuration of FIG. 12. It is contemplated herein that the smaller the core and the thinner the surrounding shells (e.g., layers) are, the greater the overall benefit will be.

In certain embodiments of the invention nano-devices, for each material, such as the inner spherical core, and for each layer, the diameter or thickness sizes can range from about 1 nm to about 900 nanometers; from about 2 nm to about 500 nm; from about 3 nm to about 300 nm; from about 4 nm to about 100 nm.

In a particular embodiment of an invention nano-device (e.g., an invention nano-battery) it is contemplated herein that a particularly suitable operating range is:

about 5 nm to about 50 nm (diameter) for the core forming a first pole (e.g., an electrode for an invention nanobattery embodiment, and the like), about 5 nm to about 50 nm (thickness) for the inner shell or layer (, e.g. to allow ion diffusion for an invention nanobattery embodiment, and the like), and about 5 nm to about 50 nm (thickness) for the outer shell forming a second pole (e.g., an electrode for an invention nanobattery embodiment, and the like). In this particular embodiment, the total nano-device (nano unit) diameter is in the range of about 15 to about 150 nm. Accordingly, in a particular embodiment of an invention nano-device (e.g., an invention nano-battery), the diameter of the core, or thickness for each of the separator layer (e.g., inner layer) and outer layer, are each selected from the group of distances consisting of: 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, and 50 nm.

In other embodiments, the total nano-device (nano unit) diameter is in the range selected from the group consisting of: from about 1 nm to about 900 nanometers; from about 2 nm to about 500 nm; from about 3 nm to about 300 nm; from about 4 nm to about 200 nm; from about 5 to about 150 nm; from about 10 to about 150; from about 15 nm to about 150 nm; from about 15 nm to about 100n m; 20 nm to about 75 nm; from about 25 nm to about 50 nm.

In yet other embodiments, for the total particle diameter, it is contemplated herein that the diameter or thickness sizes can range into the microns, such as from 1 to about 10 microns.

### Example 11—Preventing Electrical Shorts Between the Nanowire Emanating From the Core and the Outer Shell of a Nano-Device

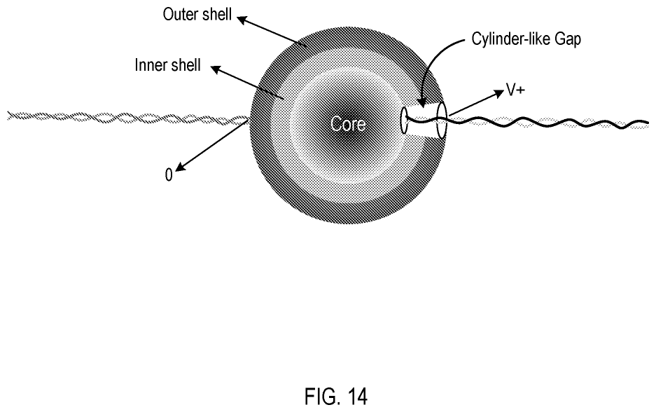

In this particular embodiment, depicted in FIG. 14, the DNA attached to the core generates a cylinder-like gap as it repels the molecules with opposing charge making up the inner and outer shells and preventing a short between the nanowire coming out of the core and the outer shell.

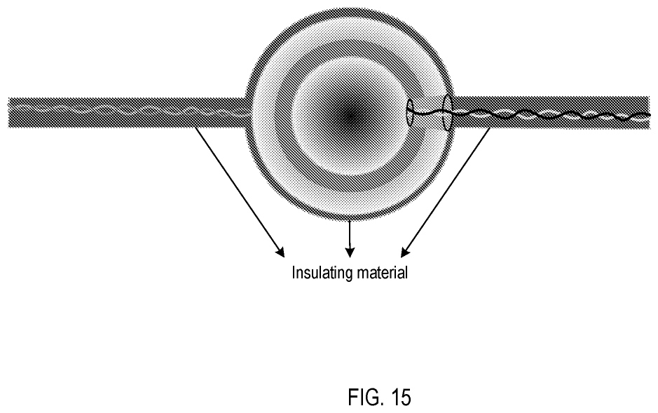

In another embodiment, as depicted in FIG. 15, any one of the following, or a combination of two or all three of the following is contemplated herein to allow prevention of an electrical short with core and outer shell:

1) DNA attached to the core could be coated with an insulating polymer before or after the growth of inner and outer shell to prevent the short between the nanowire coming out of the core and outer shell;
2) When a nanowire is attached to the outer shell, that nanowire can be coated by with insulating material;
and 3) The outer shell can also be coated with an insulating material.

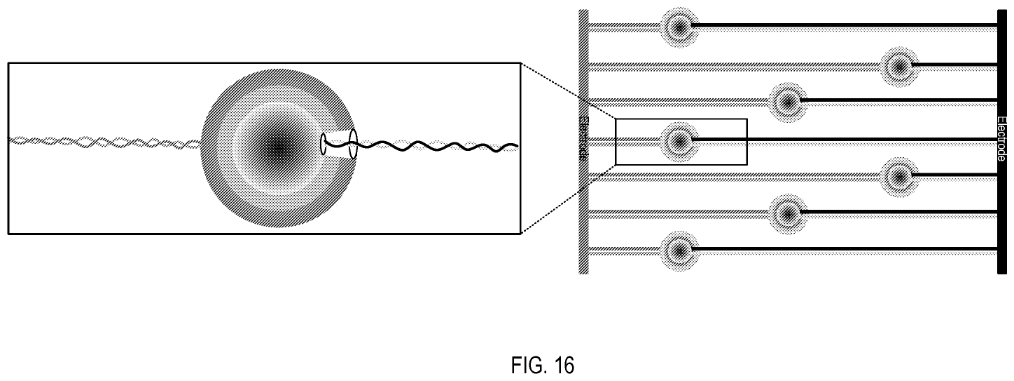

In a particular embodiment, as depicted in FIG. 16, 1 or more DNA nanowires connected to the core of a nano-component could be connected directly to one of the electrodes (dark, right-hand-side), while one or more DNA nanowires attached to outer shell of the same nano-component could be connected to the “other” electrode (light, left-hand-side). In certain embodiments, the length of the DNA nanowire(s) on each of the cores and the outer shells of the nano-components is selected to be long enough, such that each nano-component is free to self-assemble at any location within the nano-device or within the 2 electrodes; and will not be limited to a location within the nano-device by virtue of the length of the attached DNA nanowires. In other words, when a particular nano-component is modified with DNA nanowires as set forth above and combined in parallel with other nano-components for the self-assembly of a particular nano-device, each particular nano-component can be located either very near the left electrode or very near the right electrode of FIG. 16, or anywhere in between or anywhere within the nano-device.

### Example 12—Self-Assembly of Multiple Sets of Nanocomponents Integrated into a Nano-Device

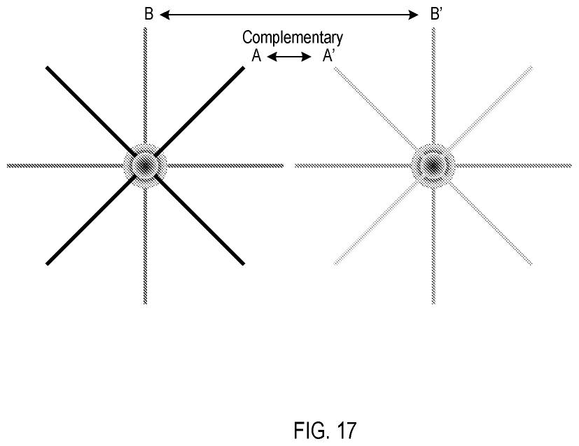

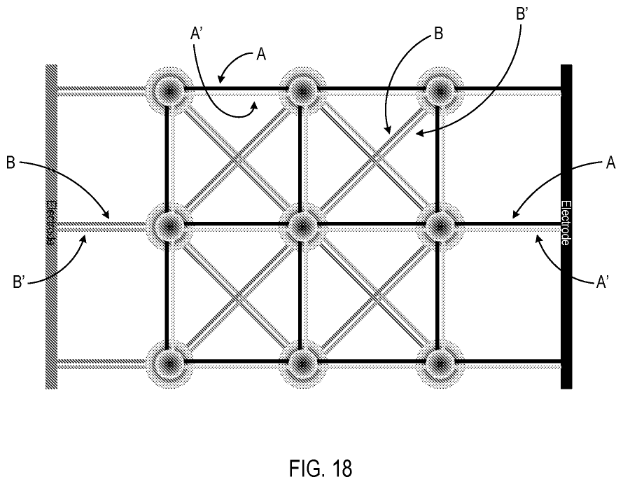

In this particular embodiment, depicted in FIG. 17, there are two different sets of nanocomponents, a first set and a second set. Each set has 1 or more single stranded oligonucleotides attached to the core and 1 or more single stranded oligonucleotides attached to the outer shell. In the first set, the single stranded oligonucleotide attached to the core has a particular sequence of bases making up the oligonucleotide, A, while the oligonucleotide(s) attached to the outer shell of the first set has a sequence B, which is different from sequence A. In the second set of nanocomponents, the sequence of 1 or more oligonucleotides attached to the core has a sequence A′, which is complementary to A while the sequence of oligonucleotides attached to the outer shell of the second set is B′, which is complementary to the sequence B. In this embodiment, the electrodes on the sides of the chamber have single stranded oligonucleotides attached with one electrode having a mixture of A and A′ oligonucleotides, while the other electrode has single stranded oligonucleotides attached with a mixture of B and B′ (see FIG. 18).

As set forth in FIG. 18, once these sets of nanocomponents (or nanoparticles) from the first and second sets are mixed in the chamber bordered by electrodes with the described single stranded oligonucleotide sequences, the nanocomponents will self-assemble to form a lattice-like structure where the cores are connected with each other through a network of double stranded DNA produced by the hybridization of A and A′; and the outer shells are connected through a network of double stranded DNA produced by the hybridization of B and B′. In this embodiment, the core network is also connected with one of the electrodes having a mixture of A and A′ oligonucleotides, while outer shell network is connected to the other electrode having a mixture of B and B′ oligonucleotides.

As used herein, the phrase “substantially all of the nano-devices,” in the context of connecting either the cores and/or the outer layers of the invention nano-devices into a network, refers to a very high percentage of either the cores or outer layers being connected within the network, with the understanding that a small percentage of either the cores or outer layers may not be connected within the network. For example, 0.001-1% of either the cores or outer layers may not be connected within the network, without altering the overall function of the particular composite-nano-device. In other embodiments, 1% up to 10% of either the cores or outer layers may not be connected within the network, without altering the overall function of the particular composite-nano-device.

### Example 13—Preparation of Conductive Nanowires

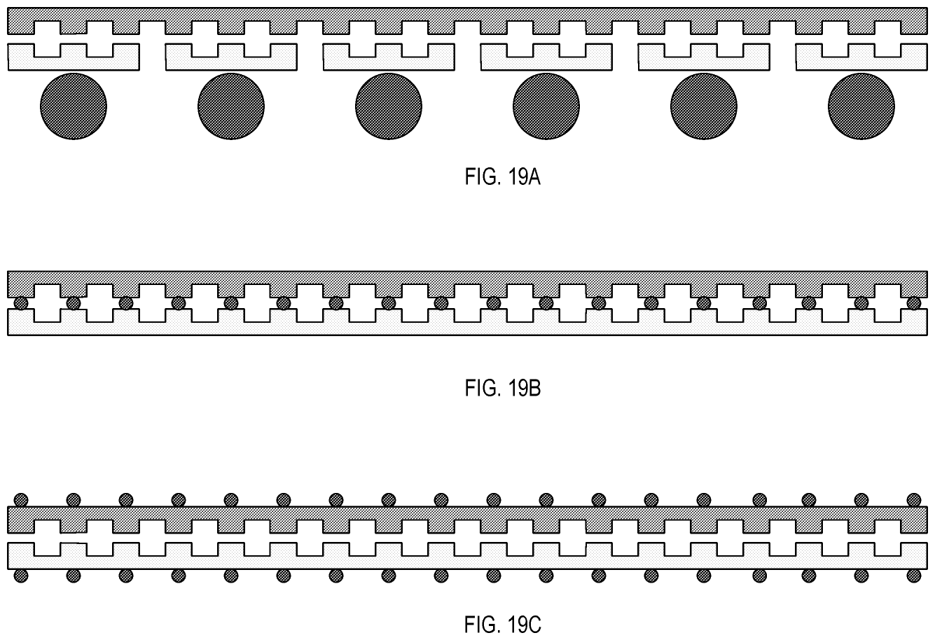

As set forth in FIG. 19A, a nanowire can be produced by the assembly of conductive nanoparticle attached oligonucleotides onto a particular DNA strand. See, for example, the methods described in Hongfei et al.: Self-Replication-Assisted Rapid Preparation of DNA Nanowires at Room Temperature and Its Biosensing Application Analytical Chemistry 2019 91 (4), 3043-3047; and Russell et al.: Gold nanowire based electrical DNA detection using rolling circle amplification (2006) ACS Nano vol: 8, issue 2, 2014, pp. 1147-; each of which are incorporated by reference herein in their entirety for all purposes.

As set forth in FIG. 19B, a nanowire can be produced by the use of intercalating conductive agents, as set forth in Braun et al.: DNA-templated assembly and electrode attachment of a conducting silver wire, (1998) Nature, 19; 391(6669): 775-8; Geng et al.: Rapid metallization of lambda DNA and DNA origami using a Pd seeding method (2011) Journal of Materials Chemistry, 21 (32), pp. 12126-12131; and Ijiro et al.: DNA-based silver nanowires fabricated by electroless plating (2006) Molecular Crystals and Liquid Crystals, 445: 1, 207/[497]-211/[501]; each of which are incorporated by reference herein in their entirety for all purposes.

As set forth in FIG. 19C, a nanowire can be produced by DNA Backbone functionalization/Charge based modification as described, for example, in Kondo et al.: A metallo-DNA nanowire with uninterrupted one-dimensional silver array (2017) Nature Chemistry, 9 (10), pp. 956-960; Keren et al.: Sequence-specific molecular lithography on single DNA molecules. (2002) Science 297, 72; and Berti et al.: DNA-templated photoinduced silver deposition (2005) J. Am. Chem. Soc. 127, 11216-11217; each of which are incorporated by reference herein in their entirety for all purposes.

### Example 14—Simulated Performance Metrics of an Invention Nano-Capacitor

For the purpose of simulating only the response of the nanocomponent itself, the nanowire length is set to 0 as the nanowire length would change depending on the assembly configuration (shown in FIG. 14). As the charge would be carried into the core along the nanowire, the point where the nanowire enters in the nanocomponent is set to +V and the voltage at the point where the other nanowire connects to the outer shell is set to 0 (see FIG. 14). Each of the 3 geometrical configurations simulated are shown in

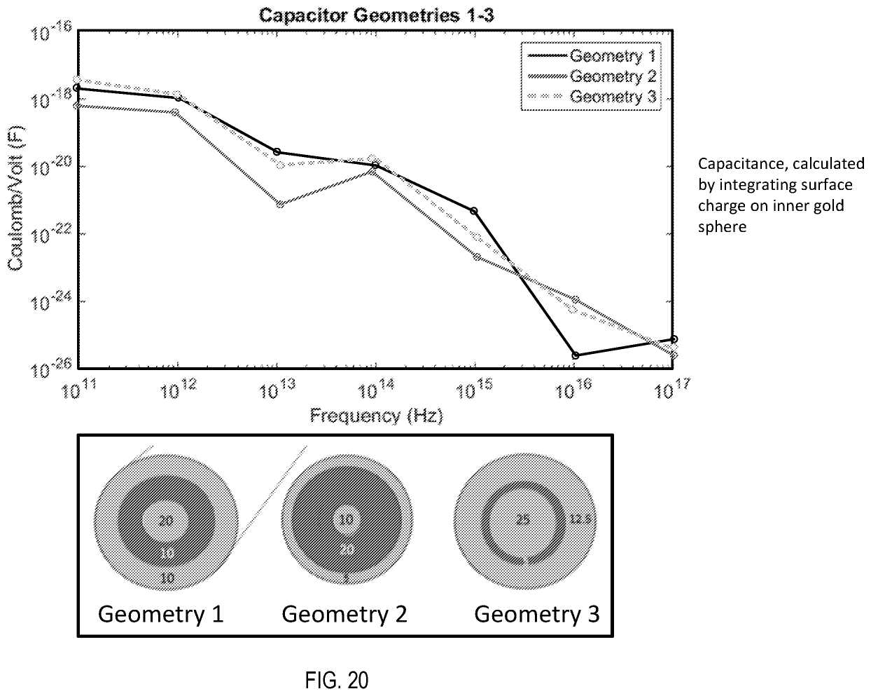

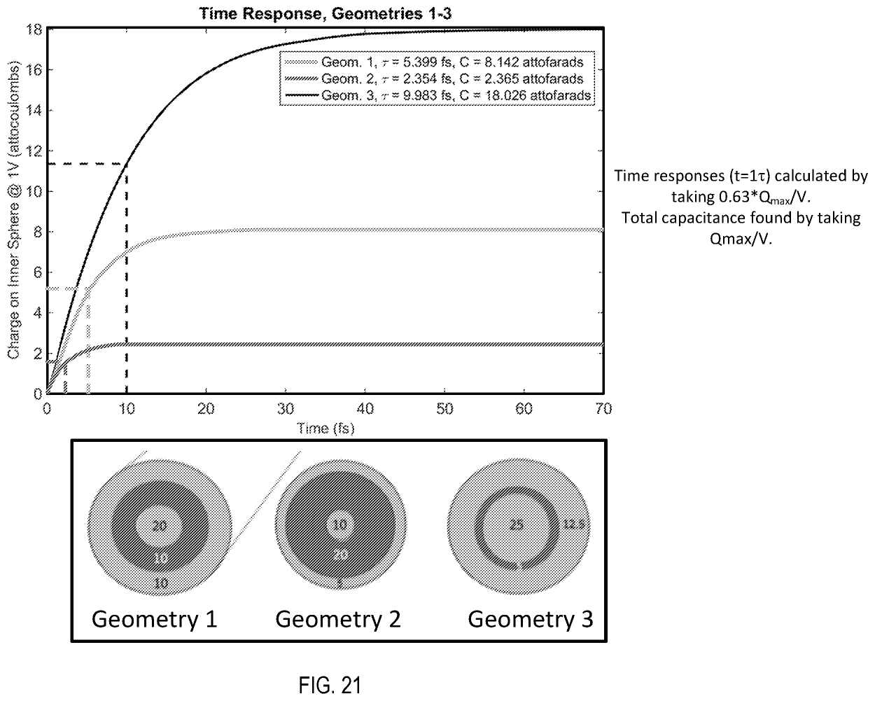

FIGS. 20 and 21. FIG. 20 shows the capacitance, calculated by integrating surface charge on inner gold sphere. From FIG. 20, it can be seen that there is a varying frequency response of the nanocomponent based on the configuration of nanocomponent. In this simulation, the outer diameter was set constant. Varying the relative dimensions of the core, inner-shell and outer-shell, one can manipulate the frequency response of the device.

FIG. 21 shows the Time responses (t=1t) calculated by taking 0.63*Qmax/V; and Total capacitance is found by taking Qmax/V. The results of the simulation indicate that the time constant for the nanocapacitor can be manipulated by the configuration of the nanocomponent. In this simulation, the outer diameter was set constant. Varying the relative dimensions of the core, inner-shell and outer-shell, one can manipulate the time response of the nanocapacitor.

1. A nanobattery comprising:
(1) an inner spherical core forming a first electrode;
(2) a separator layer positioned between the inner core and the outer layer; and
(3) an outer layer forming a second electrode.

2. The nanobattery of claim 1, wherein if the first electrode is an anode, the second electrode is a cathode; or if the first electrode is a cathode, the second electrode is an anode.

3. The nanobattery of claim 1, further comprising an external insulating layer.

4. The nanobattery of claim 1, wherein the first electrode is a cathode-core comprising a material selected from the group consisting of: Bismuth Trioxide, Cobalt Oxide Particles, Iron Disulfide, Lithium Aluminum Alloy, Lithium Carbonate, Lithium Cobalt Oxide, Lithium Cobalt Phosphate, Lithium Hydroxide, Lithium Hydroxide, Lithium Iron Phosphate (LFP), Lithium Iron(III) Oxide, Lithium Manganese Dioxide, Lithium Manganese Nickel Oxide (LMNO), Lithium Manganese Oxide (LMO), Lithium Molybdate, Lithium Nickel Cobalt Aluminum Oxide, Lithium Nickel Cobalt Oxide, Lithium Nickel Dioxide, Lithium Nickel Manganese Cobalt Oxide (NMC), Lithium Silicon Alloy, Lithium Tin Alloy, Lithium Titanate, Lithium Titanate Spinel, Manganese(IV) Oxide, Nickel Hydroxide, Silver Chromate, Silver Oxide, Vanadium Pentoxide

5. The nanobattery of claim 1, wherein the separator-layer comprises a material that is porous to allow ion diffusion.

6. The nanobattery of claim 1, wherein the outer layer is an anode comprising a material selected from the group consisting of: Carbon, Copper Carbon, Copper Chloride, Copper Sulfide, Copper(II) Oxide, Graphene, Graphene Oxide Monolayer, Graphite, Manganese Selenide, Potassium Graphite, Pyrolytic Graphite, Silicon, Tin Oxide, lithium metal and Zinc.

7. The nanobattery of claim 1, wherein the diameter of the nanobattery is selected from the group consisting of: from about 1 nm to about 900 nanometers; from about 2 nm to about 500 nm; from about 3 nm to about 300 nm; from about 4 nm to about 200 nm; from about 5 to about 150 nm; from about 10 to about 150; from about 15 nm to about 150 nm; from about 15 nm to about 100 nm; 20 nm to about 75 nm; from about 25 nm to about 50 nm.

8. The nanobattery of claim 1, wherein the diameter of the core, or thickness for each of the separator layer and outer layer, are each selected from the group consisting of: 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, and 50 nm.

9. A composite-battery-device comprising:
a plurality of nano-batteries according to claim 1, wherein each nano-battery is attached to at least 2 nanowires; and
a plurality of nanowires, wherein said plurality of nanobatteries is integrated in parallel by the nanowires connected to metal contacts.

10. The composite-battery-device of claim 9, wherein if the first electrode is an anode, the second electrode is a cathode; or if the first electrode is a cathode, the second electrode is an anode.

11. The composite-battery-device of claim 9, further comprising an external insulating layer.

12. The composite-battery-device of claim 9, wherein the first electrode is a cathode-core comprising a material selected from the group consisting of: Bismuth Trioxide, Cobalt Oxide Particles, Iron Disulfide, Lithium Aluminum Alloy, Lithium Carbonate, Lithium Cobalt Oxide, Lithium Cobalt Phosphate, Lithium Hydroxide, Lithium Hydroxide, Lithium Iron Phosphate (LFP), Lithium Iron(III) Oxide, Lithium Manganese Dioxide, Lithium Manganese Nickel Oxide (LMNO), Lithium Manganese Oxide (LMO), Lithium Molybdate, Lithium Nickel Cobalt Aluminum Oxide, Lithium Nickel Cobalt Oxide, Lithium Nickel Dioxide, Lithium Nickel Manganese Cobalt Oxide (NMC), Lithium Silicon Alloy, Lithium Tin Alloy, Lithium Titanate, Lithium Titanate Spinel, Manganese(IV) Oxide, Nickel Hydroxide, Silver Chromate, Silver Oxide, Vanadium Pentoxide

13. The composite-battery-device of claim 9, wherein the separator-layer comprises a material that is porous to allow ion diffusion.

14. The composite-battery-device of claim 9, wherein the outer layer is an anode comprising a material selected from the group consisting of: Carbon, Copper Carbon, Copper Chloride, Copper Sulfide, Copper(II) Oxide, Graphene, Graphene Oxide Monolayer, Graphite, Manganese Selenide, Potassium Graphite, Pyrolytic Graphite, Silicon, Tin Oxide, lithium metal and Zinc.

15. The composite-battery-device of claim 9, wherein the diameter of the nanobattery is selected from the group consisting of: from about 1 nm to about 900 nanometers; from about 2 nm to about 500 nm; from about 3 nm to about 300 nm; from about 4 nm to about 200 nm; from about 5 to about 150 nm; from about 10 to about 150; from about 15 nm to about 150 nm; from about 15 nm to about 100 nm; 20 nm to about 75 nm; from about 25 nm to about 50 nm.

16. The composite-battery-device of claim 9, wherein the diameter of the core, or thickness for each of the separator layer and outer layer, are each selected from the group consisting of: 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, 40, 41, 42, 43, 44, 45, 46, 47, 48, 49, and 50 nm.

17. The composite-battery-device of claim 9, wherein the nanowire comprises a metallo-nucleic acid nanowire.

18. The composite-battery-device of claim 17, wherein the nanowire comprises a silver-DNA hybrid nanowire.

19.-20. (canceled)

21. A nano-device comprising:
an inner spherical core forming a first pole;
an optional separator layer positioned between the inner core and the outer layer; and
an outer layer forming a second pole, wherein said nano-device is a nano-capacitor:
wherein the first pole is a first electrode;
wherein the separator layer comprises a dielectric material; and
wherein the second pole is a second electrode that is opposite from the first electrode.

22. A nano-device comprising:
an inner spherical core forming a first pole;
an optional separator layer positioned between the inner core and the outer layer; and
n outer layer forming a second pole, wherein said nano-device is a nano-solarcell:
wherein the first pole is either a p-type or n-type semiconductor;
wherein the separator layer comprises a light sensitive intrinsic semiconductor; and
wherein the second pole is a second p-type or n-type semiconductor that is different than the first semiconductor.

23. A nano-device comprising:
an inner spherical core forming a first pole;
an optional separator layer positioned between the inner core and the outer layer; and
an outer layer forming a second pole, wherein said nano-device is a nano-LED:
wherein the first pole is either a p-type or n-type semiconductor; and
wherein the second pole is a second p-type or n-type semiconductor that is different than the first semiconductor.

24. A nano-device comprising:
an inner spherical core forming a first pole;
an optional separator layer positioned between the inner core and the outer layer; and
an outer layer forming a second pole, wherein said nano-device is a nano-battery:
wherein the first pole is a first electrode;
wherein the separator layer comprises a comprises a material that is porous to allow ion diffusion; and
wherein the second pole is a second electrode that is opposite from the first electrode.

25. A nano-capacitor comprising:
an inner spherical core forming a first electrode;
a separator layer comprising a dielectric material, wherein said separator layer is positioned between the inner core and the outer layer; and
an outer layer forming a second electrode that is opposite from the first electrode.

26. The nano-capacitor of claim 25, wherein the first electrode is a metal selected from the group consisting of: gold, silver, iron and platinum.

27. The nano-capacitor of claim 25, wherein the dielectric material is an oxide selected from the group consisting of MgO, TiO2, SiO2, or any mixture thereof.

28. The nano-capacitor of claim 25, wherein the second electrode is a metal selected from the group consisting of: gold, silver, iron and platinum.

29. A composite-nano-capacitor-device comprising:
a plurality of nano-capacitors according to claim 25, wherein each nano-capacitor is attached to at least 2 nanowires; and
a plurality of nanowires, wherein said plurality of nano-capacitors is integrated in parallel by the nanowires connected to metal contacts.

30. The composite-nano-capacitor-device of claim 29, wherein the first electrode is a metal selected from the group consisting of: gold, silver, iron and platinum.

31. The composite-nano-capacitor-device of claim 29, wherein the dielectric material is an oxide selected from the group consisting of MgO, TiO2, SiO2, or any mixture thereof.

32. The composite-nano-capacitor-device of claim 29, wherein the second electrode is a metal selected from the group consisting of: gold, silver, iron and platinum.

33. A nano-solarcell comprising:
an inner spherical core forming a first semiconductor that is either a p-type or n-type semiconductor;
a separator layer comprising a light sensitive intrinsic semiconductor, wherein said separator layer positioned between the inner core and the outer layer; and
an outer layer forming a second p-type or n-type semiconductor that is different than the first semiconductor.

34. A composite-nano-solarcell-device comprising:
a plurality of nano-solarcells according to claim 33, wherein each nano-solarcell is attached to at least 2 nanowires; and
a plurality of nanowires, wherein said plurality of nano-solarcells is integrated in parallel by the nanowires connected to metal contacts.

35.-37. (canceled)

38. A composite-nano-device, comprising a first set and a second set of nano-devices comprising:
an inner spherical core forming a first pole;
an optional separator layer positioned between the inner core and the outer layer; and
an outer layer forming a second pole,
wherein each of the first and second set has 1 or more single stranded oligonucleotides attached to the core forming a first pole and 1 or more single stranded oligonucleotides attached to the outer layer forming the second pole.

39. The composite-nano-device of claim 38, wherein in the first set, the single stranded oligonucleotide(s) attached to the core has an oligonucleotide sequence A, and the oligonucleotide(s) attached to the outer layer of the first set has an oligonucleotide sequence B, which is different from sequence A.

40.-43. (canceled)

44. The nano-device of claim 21, further comprising an external coating layer.

45. The nano-device of claim 22, further comprising an external coating layer.

46. The nano-device of claim 23, further comprising an external coating layer.

47. The nano-device of claim 24, further comprising an external coating layer.
